(19) United States
(12) Patent Application Publication
(10) Pub. No.: US 2012/0086068 A1
(43) Pub. Date: Apr. 12, 2012

(54) METHOD FOR DEPOSITING A DIELECTRIC ONTO A FLOATING GATE FOR STRAINED SEMICONDUCTOR DEVICES

(75) Inventor: Andrew E. Horch, Seattle, WA (US)

(73) Assignee: SYNOPSYS INC., Mountain View, CA (US)

(21) Appl. No.: 12/898,737

(22) Filed: Oct. 6, 2010

(51) Int. Cl. H01L 27/092; H01L 21/8238

(52) U.S. Cl. 257/324; 438/169; 257/E21.632; 257/E27.062

(57) ABSTRACT

A method for forming a semiconductor device and a corresponding device are provided. The method includes forming a floating gate device in a process with dual strain layers, and an etch stop layer. An oxide is formed between the floating gate device and a nitride layer above the floating gate.

### FIELD

The present disclosure generally relates to semiconductor devices and, in particular, relates to reducing undesirable leakage current in semiconductor devices.

### BACKGROUND

Transistors fabricated in a standard logic complementary metal oxide semiconductor (CMOS) process for a Non-volatile Memory (NVM) device may have gate oxides that enable the NVM to retain charge on a floating gate. Typically starting with 0.25 μm devices, an etch stop layer may be added to an Inter Level Dielectric (ILD) stack located between the gate and a first level of metal. The etch stop layer is typically composed of a nitride film, e.g., Si₃N₄ or SiON. The nitride film may be either conductive or may have large number of traps. The charge stored in the floating gate may leak through the etch stop layer if the nitride films are too close to the floating gate (<100 A). A way is needed, therefore, to add a dielectric, such as SiO₂, or increase the amount of an existing dielectric between the floating gate and the nitride film in order to reduce the leakage current so that the device may function properly.

One known solution to the problem is to add a salicide block film to buffer the floating gate from the etch stop layer. The salicide block film may be formed by depositing SiO₂ after a source/drain activation annealing and selectively etching the deposited SiO₂ layer to form a salicide block layer. The salicide block layer is common in CMOS processes. The salicide block layer is used to form high resistance elements such as resistors in the process. In some processes, instead of depositing an oxide layer, a mask can be added to selectively keep some of the gate spacer material where salicide needs to be blocked. Thus, a salicide block may be integrated into a spacer module to eliminate a deposition step. Since the “integrated” spacer may be used as both the spacer and the salicide block, the spacer cannot be modified without affecting the performance of the device. In advanced CMOS processes, a portion of the gate spacer is made out of nitride. If the floating gate has the salicide block over it, the floating gate may have the nitride of the spacer of the salicide block in contact or <100 A from the floating gate. If the salicide block mask is not used the floating gate may have the ILD etch stop layer in contact with the floating gate. As a result, the known method of buffering the floating gate from the etch stop may not be possible for reducing leakage. There is therefore a need for a method to solve the above mentioned problems.

### SUMMARY

In accordance with various embodiments of the invention, a method of forming a semiconductor device is provided. In some embodiments, the method comprises forming a floating gate device, forming a second device of first dopant type; forming a third device of a second dopant type, the third device being coupled between the floating gate device and the second device; depositing a first stress layer above at least the second device; depositing a second stress layer above at least the third device; depositing a layer comprising a dielectric above the floating gate device after depositing the first and second stress layers; and fabricating an etch stop layer above the first stress layer, second stress layer, and the dielectric layer.

The dielectric layer may comprise a dielectric such as SiO2. According to some embodiments, the method may include depositing a conductive layer to be used as a control gate; selectively removing the dielectric layer and control gate, and fabricating an etch stop layer above all three devices. According to various embodiments, if the conductive control gate layer is deposited it must be selectively removed.

In some embodiments, the second and third devices are complementary device types. The second device may include a gate stack over a semiconductor body, the gate stack being separated from a substrate by an insulating region, a source region formed of a first dopant type in the semiconductor body with a second doping type below the gate stack, a drain region formed of a first dopant type in the semiconductor body on another side of the gate stack. In some embodiments, the third device is formed by repeating the device formation process for the second device while using opposite dopant types, such that the second device and third device are complementary device types. In some embodiments, the floating gate device is formed in a similar manner to the first and second devices.

### BRIEF DESCRIPTION OF THE DRAWINGS

FIG. 1 illustrates a method of forming the semiconductor device in accordance with various embodiments.

FIG. 2 illustrates schematically certain aspects of a semiconductor device for reducing leakage current in accordance with some embodiments.

FIG. 3 illustrates a method of forming the semiconductor device in accordance with various embodiments.

FIG. 4 illustrates aspects of the semiconductor device according to some embodiments.

FIG. 5 illustrates aspects of the semiconductor device including use of a conductive film, according to various embodiments.

### DETAILED DESCRIPTION OF THE EMBODIMENTS

Various embodiments described provide a method and corresponding semiconductor device to reduce leakage. In some embodiments, the semiconductor device is a non-volatile memory.

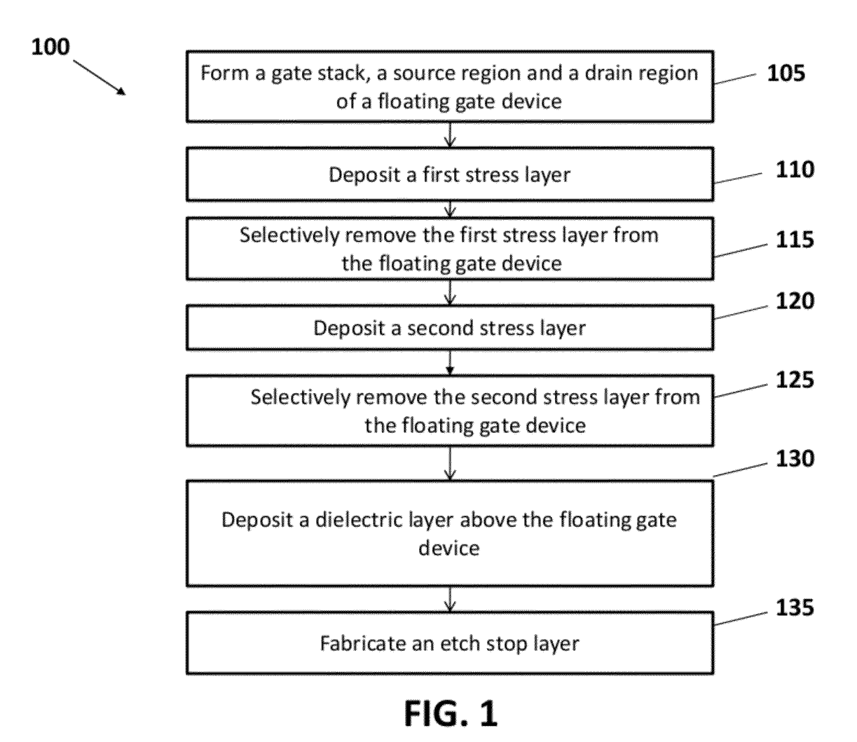

FIG. 1 illustrates a method 100 of forming the semiconductor device in accordance with various embodiments. The semiconductor device may include a floating gate device. At step 105, a gate stack, a source region, and a drain region of the floating gate device are formed. The source region and drain region may also be referred to herein as the source and drain, respectively. The gate stack may be separated from a substrate by an insulating region. The source region may be configured to emit electrons and the drain may be configured to collect electrons. The floating gate is configured to control a flow of electrons from the source to the drain.

The semiconductor device may also include an n-dopant type (n-type) metal oxide semiconductor (NMOS) device, and a p-dopant type (p-type) metal oxide semiconductor (PMOS) device. Strained silicon may be used to improve the mobility of the channel of a MOS device to obtain higher performance. Strained devices may be formed by compressing PMOS devices to get better hole mobility and by stretching NMOS devices to get better electron mobility. Node stressor films may be used to provide straining. A compressive nitride film may be added atop PMOS devices to increase hole mobility. For NMOS devices, a tensile nitride film may be added atop the device to increase electron mobility. A third nitride film may also be added to cover all devices to providing an etch stop layer/diffusion barrier. According to various embodiments, the selective addition of stressor films may be used to provide the opportunity to add or thicken an oxide film between the floating gate and the nitride layers above the floating gate for overcoming the above-mentioned problem of leakage of charge from the floating gate.

At step 110, a first stress layer is deposited. At step 115, the first stress layer may be selectively removed from the floating gate device. According to some embodiments, etching may be used to selectively remove the first stress layer from the floating gate device and the PMOS device. At step 120, a second stress layer may be deposited. At step 125, the second stress layer may be selectively removed from the floating gate device. According to some embodiments, etching may be used to selectively remove the second stress layer from the floating gate device and from the NMOS device. As a result, the first stress layer is layered above selective semiconductor devices, and the second stress layer is layered above other selected devices. The stress layer preferably includes a stress film. Both stress layers or films may be stripped from on top of the floating gate. Depositing the first stress layer may include depositing a nitride layer. In some embodiments, depositing the second stress layer includes depositing a nitride layer.

Forming the first stress layer may include forming a tensile layer above the NMOS device portion. In some embodiments, forming the second stress layer may include forming a compressive layer above the PMOS device portion.

At step 130, a layer including a dielectric material may be deposited above the floating gate device. In some embodiments, the dielectric layer may be deposited after steps 110-125 have been done. The dielectric layer may include, but is not limited to, silicon dioxide (SiO₂).

At step 135, an etch stop layer may be fabricated. The etch stop layer may be fabricated above the first stress layer, second stress layer, and the dielectric layer.

In some embodiments, the interconnections may be provided between the source, the drain, and the gate stack.

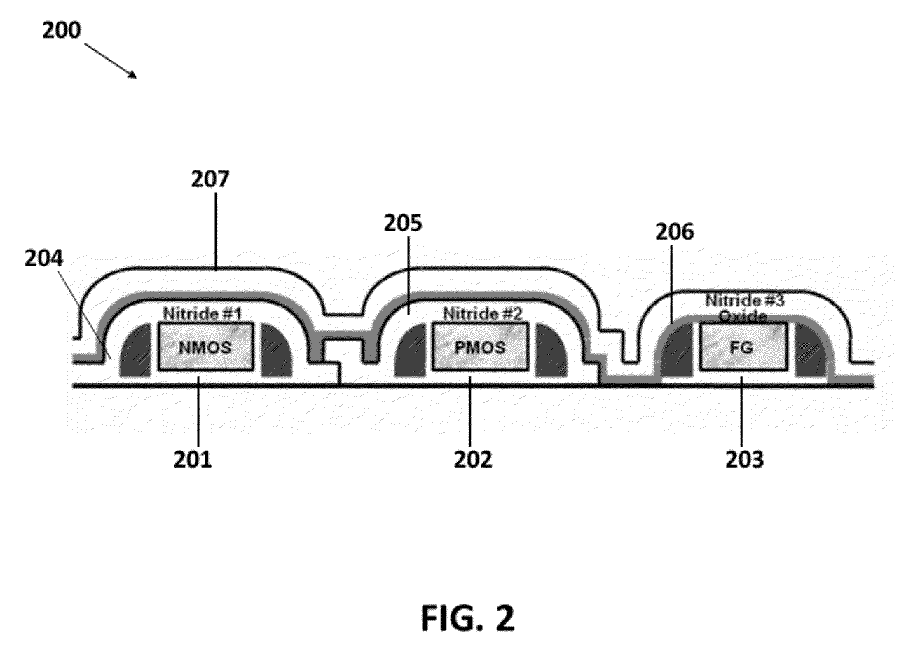

FIG. 2 illustrates schematically certain aspects of an exemplary semiconductor device 200 for reducing leakage current in accordance with some embodiments. More specifically, FIG. 2 illustrates an example of the result of the process 100 in accordance with various embodiments. The semiconductor device 200 may comprise a non-volatile memory. The semiconductor device 200 includes a device 201, a device 202, and a floating gate device 203. As shown in the embodiment in FIG. 2, the device 202 may be coupled between the device 201 and the floating gate device 203. The floating gate device 203 is also identified as FG in FIG. 2. The device 201 may include an n-type metal oxide semiconductor (NMOS) device, i.e., NMOS device 201. The device 202 may be configured as a p-type metal oxide semiconductor (PMOS) device, i.e., PMOS device 202. The floating gate device 203 may include a gate stack configured as a floating gate. The gate stack may operate as a non-volatile memory element controlling the flow of electrons from the source to the drain of floating gate device 203.

The semiconductor device 200 may also include the first stress layer 204 above the NMOS device 201. The first stress layer 204 may include a nitride and is identified as “Nitride #1” in the example in FIG. 2. In some embodiments, the first stress layer 204 is a tensile layer. The first stress layer 204 may be configured to stretch the NMOS device 201. FIG. 2 shows the devices in the process flow prior to the metal interconnects being formed.

The semiconductor device 200 may include a second stress layer 205 above the PMOS device 202. The second stress layer 205 may be a compressive layer. In some embodiments, the second stress layer 205 includes a nitride and is identified as “Nitride #2” in the example in FIG. 2. The second stress layer 205 may be configured to compress the PMOS device 202.

According to various embodiments, a dielectric layer 206 may be deposited above the floating gate device 203. The semiconductor device 200 may also include an etch stop layer 207 disposed above the first stress layer 204, second stress layer 205, and the dielectric layer 206. The dielectric layer 206 may be configured between the second stress layer 205 and an etch stop layer 207 to prevent leakage of the flow of electrons via the gate stack of the floating gate device 203. The dielectric layer 206 may include silicon oxide, e.g., silicon dioxide or SiO₂. In some embodiments, an interconnection between the source 201, the drain 202, and the floating gate 203 is included.

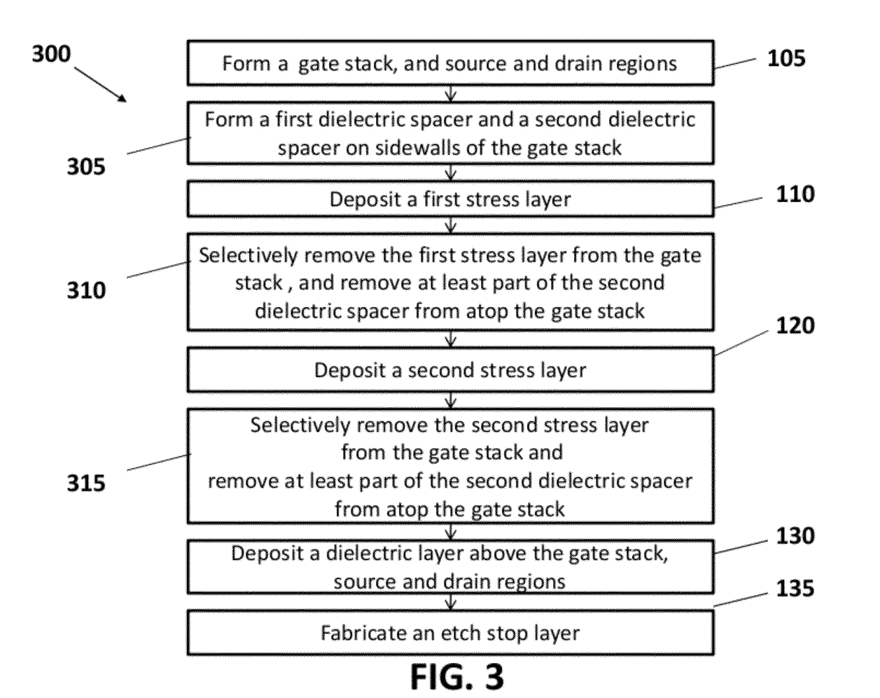

FIG. 3 illustrates a method 300 of forming the semiconductor device in accordance with various embodiments. The method 300 is similar to the method 100 in FIG. 1, except for the addition of step 305, and for step 115 being replaced by step 310, and step 125 being replaced by step 315.

Most 45 nm and more advanced processes use double spacer processes. In a double spacer process, a first spacer comprised of a dielectric, such as SiO₂, may be used to offset/self align an implant from a floating gate. A second spacer comprised of a dielectric such as nitride may be used to increase the offset of another implant from the floating gate. The side wall may be thick enough, but the oxide on top of the floating gate may not be thick enough for the device to function properly.

At step 105, a source region, a drain region, and a gate stack of a floating gate device may be formed. The semiconductor device may also include an n-dopant type (n-type) metal oxide semiconductor (NMOS) device, and a p-dopant type (p-type) metal oxide semiconductor (PMOS) device.

At step 305, a first dielectric spacer and a second dielectric spacer are formed on sidewalls of the gate stack of the floating gate device. The first dielectric spacer and second dielectric spacer may form a “double spacer”. The first dielectric may comprise silicon oxide. During a spacer etch of the first dielectric; the silicon dioxide is removed from the top of the gate stack of the floating gate device. In some embodiments, the second dielectric comprises a silicon nitride. The spacer nitride is also used as a salicide block layer. In processes where the spacer nitride is also used as a salicide block dielectric, adding another dielectric, such as SiO2, is desired. The floating gate may or may not be salicided. Some salicide materials can affect the retention (leakage) of the floating gate. Depending on the salicidation process, the floating gate may or may not need to be salicide free. In some process, the salicide block layer is used purely as a buffer between the floating gate and a nitride etch stop layer.

At step 110, a first stress layer is deposited.

At step 310, the first stress layer is selectively removed from the gate stack of the floating gate device, and at least part of the second dielectric spacer is removed from atop the gate stack. An etch may be used to remove the first stress layer from the gate stack and also from a PMOS device (see e.g., PMOS device 202 in FIG. 2). In some embodiments, the removal of at least part of the second dielectric spacer in step 310 is achieved by increasing the over etch portion of an etch used for removing the first stress layer from the PMOS device 202 and the floating gate device 203.

At step 120, a second stress layer may be deposited.

At step 315, the second stress layer is selectively removed from the gate stack of the floating gate device, and at least part of the second dielectric spacer from is removed from atop the gate stack. An etch may be used to remove the second stress layer from the gate stack of the floating gate device and also from an NMOS device (see e.g., NMOS device 201 in FIG. 2). According to various embodiments, the removal of at least part of the second dielectric spacer in step 315 is achieved by increasing the over etch portion of an etch used for removing the second stress layer from the NMOS device 201 and the floating gate device 203. The entirety of the second dielectric spacer may be removed from atop the gate stack of the floating gate device through the operation of steps 310 and 315. The second dielectric spacer may be removed from atop the gate stack before step 130 is performed. At step 130, the dielectric layer is deposited above the gate stack, the drain region, and the source region of the floating gate device. In some embodiments, a conductive film in deposited atop the dielectric layer. In embodiments where the conductive film is deposited, it must be selectively removed.

At step 135, an etch stop layer may be fabricated.

According to various embodiments, the first and second stress layers are removed from the floating gate stack of the floating gate device before depositing the dielectric layer.

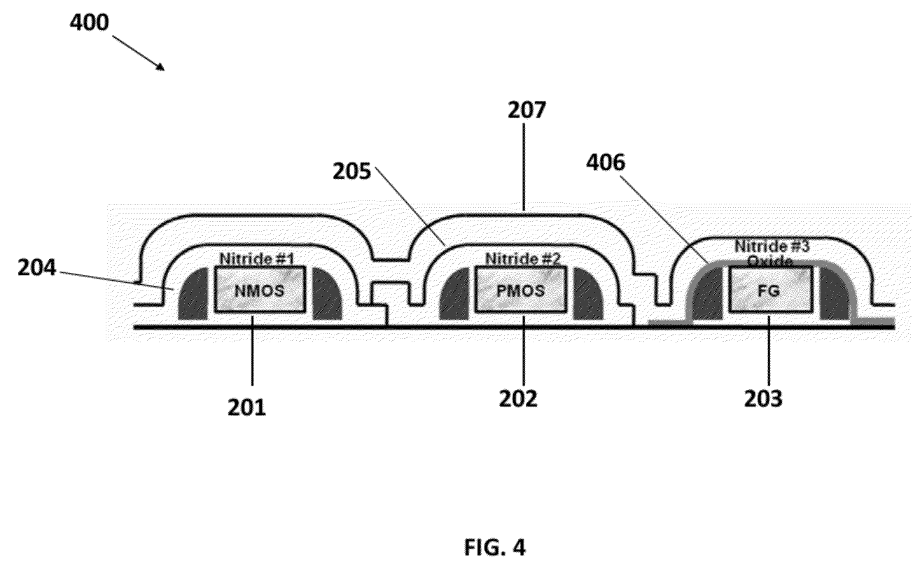

A mask may be provided for selectively removing the dielectric layer. FIG. 4 illustrates aspects of the semiconductor device 400 according to some embodiments. The semiconductor device 400 is similar to the semiconductor device 200 in FIG. 2, except that the dielectric layer 406 differs from the dielectric layer 206 in FIG. 2 due to the use of the mask. In some embodiments, an etch is used to remove the dielectric layer. The mask functions to stop removal of the dielectric layer from over the floating gate device 203. As a result of the use of the mask, the dielectric layer is removed from the NMOS device 201 and the PMOS device 201, but not from the floating gate device 203, as illustrated in the example in FIG. 4.

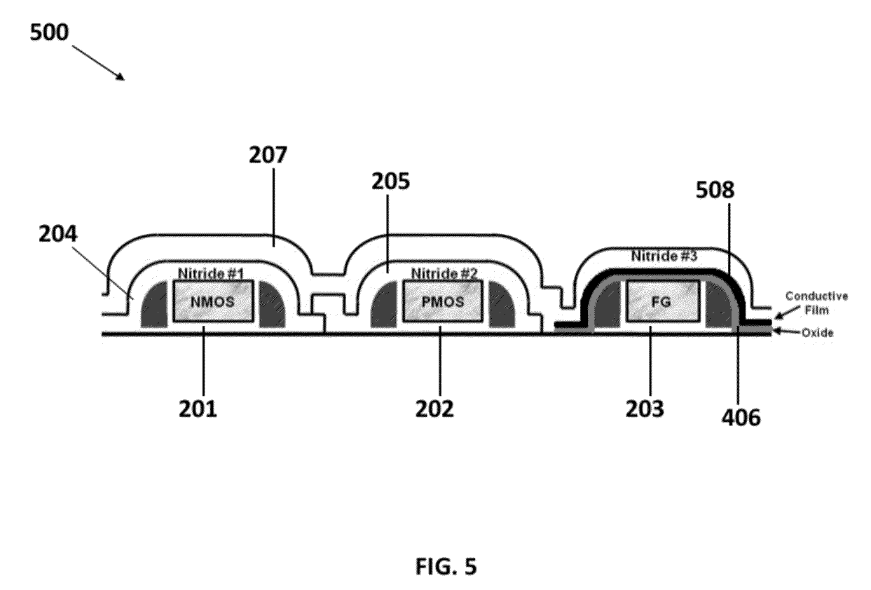

FIG. 5 illustrates aspects of the semiconductor device 500 including use of a conductive film 508, according to various embodiments. The semiconductor device 500 is similar to the semiconductor device 400 in FIG. 4, except that semiconductor device 500 includes the conductive film 508 deposited atop the dielectric layer above the floating gate device 203. The deposition may include selective etching. In some embodiments, the conductive film comprises a doped poly silicon or a metal. The conductive film may be used as a capacitor coupled to the floating gate.

What is claimed is:

1. A method of forming a semiconductor device comprising:
forming a floating gate device;
forming a second device of first dopant type;
forming a third device of a second dopant type, the third device being coupled between the floating gate device and the second device;
depositing a first stress layer above at least the second device;
depositing a second stress layer above at least the third device;
depositing a layer comprising a dielectric above the floating gate device after depositing the first and second stress layers; and
fabricating an etch stop layer above the first stress layer, second stress layer, and the dielectric layer.

2. The method of claim 1, wherein the first dopant type is n-type such that the second device comprises an n-type metal oxide semiconductor (NMOS) device.

3. The method of claim 2, wherein the second dopant type is p-type such that the third device comprises a p-type metal oxide semiconductor (PMOS) device.

4. The method of claim 3, wherein one of the stress layers comprises a tensile layer disposed above the NMOS device, and other stress layer comprises a compressive layer disposed above the PMOS device.

5. The method of claim 1, wherein the first stress layer and second stress layer each comprise a nitride layer.

6. The method of claim 1, wherein the first stress layer forms a tensile layer and the second stress layer forms a compressive layer.

7. The method of claim 1, wherein the dielectric layer comprises a silicon dioxide (SiO₂) layer.

8. The method of claim 1, further comprising forming a double spacer on sidewalls of a gate stack of the floating gate device, the double spacer including a first dielectric spacer and a second dielectric spacer.

9. The method of claim 8, wherein the first dielectric spacer comprises a silicon oxide spacer.

10. The method of claim 8, wherein the second dielectric spacer comprises a silicon nitride spacer.

11. The method of claim 8, further comprising removing the second dielectric spacer from atop the gate stack of the floating gate device before depositing the dielectric layer.

12. The method of claim 8, further comprising depositing the first and second stress layers above the gate stack of the floating gate device, and removing the first and second stress layers from the gate stack of the floating gate device using a respective etch after deposition of each of the respective stress layers.

13. The method of claim 12, further comprising, during the respective etches, removing the second dielectric spacer from atop the gate stack of the floating gate.

14. The method of claim 13, further comprising providing a mask for selectively removing the dielectric layer from above the second device and the third device.

15. The method of claim 14, further comprising depositing a conductive film atop the dielectric layer above the floating gate device, wherein the conductive film comprises a doped poly silicon or a metal.

16. The method of claim 1, further comprising providing a mask for selectively removing the dielectric layer from above the second device and above the third device.

17. The method of claim 16, further comprising depositing a conductive film atop the dielectric layer above the floating gate device.

18. The method of claim 17, wherein the conductive film comprises a doped poly silicon or a metal.

19. The method of claim 1, wherein the semiconductor device comprises a non-volatile memory (NVM) device.

20. The method of claim 1, further comprising providing interconnections between the floating gate device, the second device, and the third device.

21. The method of claim 1, wherein the second device comprises a gate stack over a semiconductor body, the gate stack being separated from a substrate by an insulating region source region formed of a first dopant type in the semiconductor body with a second doping type on one side of the gate stack, and a drain region formed of a first dopant type in the semiconductor body on another side of the gate stack.

22. The method of claim 21, wherein the third device is formed such that the second and third devices are complementary device types.

23. The method of claim 1, wherein the floating gate device comprises a source region, a drain region, and a first gate stack separated from a substrate by a first insulating region.

24. A semiconductor device having a semiconductor body, the semiconductor device comprising:
a floating gate device;
a second device of first dopant type, the first dopant type being n-type such that the second device comprises an n-type metal oxide semiconductor (NMOS) device;
a third device of a second dopant type, wherein the second dopant type is p-type such that the third device comprises a p-type metal oxide semiconductor (PMOS) device, the third device being coupled between the floating gate device and the second device;
a first stress layer deposited above at least the second device;
a second stress layer deposited above at least the third device;
a dielectric layer deposited above the floating gate device after depositing the first and second stress layers; and
an etch stop layer fabricated above the first stress layer, second stress layer, and the dielectric layer.

25. The semiconductor device of claim 24, wherein one of the stress layers comprises a tensile layer disposed above the NMOS device, and other stress layer comprises a compressive layer disposed above the PMOS device.

26. The semiconductor device of claim 24, wherein the first stress layer and second stress layer each comprise a nitride layer.

27. The semiconductor device of claim 24, wherein the first stress layer forms a tensile layer and the second stress layer forms a compressive layer.

28. The semiconductor device of claim 24, wherein the second stress layer comprises a compressive layer.

29. The semiconductor device of claim 24, wherein the dielectric layer comprises a silicon dioxide (SiO₂) layer.

30. The semiconductor device of claim 24, further comprising a double spacer formed on sidewalls of a gate stack of the floating gate device, the double spacer including a first dielectric spacer and a second dielectric spacer.

31. The semiconductor device of claim 30, wherein the first dielectric spacer comprises a silicon oxide spacer.

32. The semiconductor device of claim 30, wherein the second dielectric spacer comprises a silicon nitride spacer.

33. The semiconductor device of claim 30, wherein the second dielectric spacer is removed from atop the gate stack of the floating gate device before depositing the dielectric layer.

34. The semiconductor device of claim 30, wherein the first and second stress layers are deposited above the gate stack of the floating gate device, and the first and second stress layers are removed from the gate stack of the floating gate device using a respective etch after deposition of each of the respective stress layers.

35. The semiconductor device of claim 34, further comprising, during the respective etches, removing the second dielectric spacer from atop the gate stack of the floating gate.

36. The semiconductor device of claim 35, further comprising a mask for selectively removing the dielectric layer from above the second device and the third device.

36. The semiconductor device of claim 36, further comprising a conductive film deposited atop the dielectric layer above the floating gate device, wherein the conductive film comprises a doped poly silicon or a metal.

37. The semiconductor device of claim 24, wherein the semiconductor device comprises a non-volatile memory (NVM) device.

38. The semiconductor device of claim 24, further comprising interconnections between the floating gate device, the second device, and the third device.

39. A semiconductor device formed on a substrate, the semiconductor device comprising:
a PMOS device having a compressive film thereover;
an NMOS device having a tensile film thereover;
a salicide block layer at least partially comprised of nitride; and
a floating gate device having an SiO₂ dielectric layer deposited thereon, the salicide block layer being deposited at least on the floating gate device, such that the SiO₂ dielectric layer is positioned atop the floating gate device and beneath any of the nitride deposited on the floating gate device; and
an etch stop layer deposited over the PMOS, NMOS, and floating gate devices.

40. A semiconductor device formed on a substrate, the semiconductor device comprising:
a PMOS device having a compressive film thereover;
an NMOS device having a tensile film thereover;
a floating gate device having an oxide film and a conductive film deposited thereon, the conductive film being formed over the oxide film and beneath any nitride deposited on the floating gate device; and
an etch stop layer over the NMOS, PMOS, and floating gate devices formed in the substrate.
